(19) United States
(12) Patent Application Publication
(10) Pub. No.: US 2026/0165071 A1
(43) Pub. Date: Jun. 11, 2026

(54) WAFER PROCESSING APPARATUS

(71) Applicant: MEERE COMPANY INC., Hwaseong-si (KR)

(72) Inventor: Young Hui BAK, Suwon-si (KR)

(73) Assignee: MEERE COMPANY INC., Hwaseong-si, (KR)

(21) Appl. No.: 19/415,568

(22) Filed: Dec. 10, 2025

(30) Foreign Application Priority Data
Dec. 11, 2024 (KR) 10-2024-0183854

(51) Int. Cl. H10P 72/00; H10P 72/30

(52) U.S. Cl. CPC H10P 72/0428; H10P 72/0408; H10P 72/0472; H10P 72/3202

(57) ABSTRACT

Provided is a wafer processing apparatus, including a turn table which rotates around a center axis and is positioned in alignment with a grinding area for grinding a wafer and a polishing area for polishing a wafer, a plurality of chuck tables arranged on the turn table and configured to seat the wafers, a grinding member for grinding the wafer positioned in the grinding area, a polishing member for polishing the wafer ground by the grinding member, a frame separating the grinding area and the polishing area from each other on the turn table, and a moisture removal unit arranged on the frame and for removing moisture from the wafer which moves from the grinding area to the polishing area by rotation of the turn table.

### CROSS-REFERENCE TO RELATED APPLICATION

This application is based on and claims priority under 35 U.S.C. § 119 to Korean Patent Application No. 10-2024-0183854, filed on Dec. 11, 2024, in the Korean Intellectual Property Office, the disclosure of which is incorporated by reference herein in its entirety.

### BACKGROUND

### 1. Field

The disclosure relates to a wafer processing apparatus.

### 2. Description of the Related Art

Polishing refers to smoothing a surface of a certain workpiece by rubbing the workpiece with another object. In particular, in a wafer analysis process, polishing a cut wafer analysis sample is generally performed as an essential process in the wafer analysis process. Meanwhile, a wafer polishing process is generally performed by using chemical and mechanical polishing methods. Chemical and mechanical polishing each refer to a method of polishing a workpiece such as a wafer by contacting the workpiece with a polishing pad or the like and then supplying polishing water thereto.

To achieve miniaturization and weight reduction of a semiconductor wafer, a back surface of the wafer is ground to a certain thickness. However, when the back surface of the wafer is ground, a grinding deformation layer of about 1 μm including microcracks is created on the back surface of the wafer, and when a thickness of the wafer is reduced to 100 μm or less, there is a problem that a flexural strength of a semiconductor element is reduced.

To solve such a problem, the back surface of the wafer is ground to a predetermined thickness, and then a polishing process is performed on the back surface of the semiconductor wafer to remove the grinding deformation layer formed on the back surface of the wafer and prevent a decrease in the flexural strength of the semiconductor wafer.

Dry polishing is mainly used in the polishing process, as the dry polishing does not require supplying slurry during the polishing process and does not cause waste liquid disposal.

However, because the dry polishing requires the most processing time during the polishing process, there is a need to reduce wafer drying time to reduce the overall polishing process time.

### SUMMARY

The disclosure aims to provide a wafer processing apparatus which improves productivity by arranging a moisture removal unit between a grinding area and a polishing area to shorten drying time during a wafer dry polishing process.

The technical problems to be solved by the disclosure are not limited to the technical problems mentioned above, and other technical problems not mentioned may be clearly understood by a person having ordinary skill in the technical field to which the disclosure belongs from the description below.

A wafer processing apparatus according to an embodiment of the disclosure may include a turn table which rotates around a center axis and is positioned in alignment with a grinding area for grinding a wafer and in a polishing area for polishing a wafer, a plurality of chuck tables arranged on the turn table and configured to seat the wafers, a grinding member for grinding the wafer positioned in the grinding area, a polishing member for polishing the wafer ground by the grinding member, a frame separating the grinding area and the polishing area from each other on the turn table, and a moisture removal unit arranged on the frame and for removing moisture from the wafer which moves from the grinding area to the polishing area by rotation of the turn table.

In an embodiment of the disclosure, the moisture removal unit may include an air nozzle which sprays gas at a preset angle toward the wafer.

In an embodiment of the disclosure, the grinding member may include a grinding wheel and a first rotating member for rotating the grinding wheel.

In an embodiment of the disclosure, the polishing member may include a polishing wheel and a second rotating member for rotating the polishing wheel.

In an embodiment of the disclosure, the wafer processing apparatus may include a swing nozzle which is arranged between each of the chuck tables and the polishing wheel to spray gas toward the wafer.

In an embodiment of the disclosure, the wafer processing apparatus may include a swing nozzle cover which extends from the swing nozzle to cover in between the chuck table and the polishing wheel.

In an embodiment of the disclosure, the swing nozzle cover may include a column portion which extends from the swing nozzle in a direction intersecting with a direction in which the swing nozzle moves, and a wing portion which extends from an end of the column portion in a direction parallel to the direction in which the swing nozzle moves.

In an embodiment of the disclosure, in case that the swing nozzle is positioned between the chuck table and the polishing wheel, a width of the wing portion may be greater than the longest distance from the swing nozzle to an edge of the polishing wheel when viewed in a plan view.

In an embodiment of the disclosure, a height of the column portion may be shorter than a distance from the swing nozzle to the polishing wheel.

In an embodiment of the disclosure, a wafer processing apparatus may include a turn table which rotates around a center axis and is positioned in alignment with a grinding area for grinding a wafer and a polishing area for polishing a wafer, a plurality of chuck tables arranged on the turn table and configured to seat the wafers, a grinding member for grinding the wafer positioned in the grinding area, a polishing member for polishing the wafer ground by the grinding member, and a frame separating the grinding area and the polishing area from each other on the turn table, and the polishing area may include a swing nozzle arranged between each of the chuck tables and the polishing member to spray gas toward the wafer, and a swing nozzle cover extending from the swing nozzle to cover in between the chuck table and the polishing wheel.

In an embodiment of the disclosure, the swing nozzle cover may include a column portion which extends from the swing nozzle toward the polishing wheel and a wing portion which extends from the column portion toward a center of the chuck table.

In an embodiment of the disclosure, in case that the swing nozzle is positioned between the chuck table and the polishing wheel, a width of the wing portion may be greater than the longest distance from the swing nozzle to an edge of the polishing wheel when viewed in a plan view.

In an embodiment of the disclosure, a height of the column portion may be shorter than a distance from the swing nozzle to the polishing wheel.

Other aspects, features and advantages other than those described above will become apparent from the following drawings, claims and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a perspective view of a wafer processing apparatus according to an embodiment of the disclosure;

FIG. 2 is a plan view of the wafer processing apparatus of FIG. 1;

FIG. 3 is a drawing illustrating a portion of a polishing area of the wafer processing apparatus of FIG. 1;

FIG. 4 is a side view of the polishing area of the wafer processing apparatus of FIG. 1; and

FIG. 5 is a plan view of FIG. 4 viewed from above.

### DETAILED DESCRIPTION

Hereinafter, the disclosure will be described with reference to the attached drawings. However, the disclosure may be implemented in many different forms and is therefore not limited to the embodiments described herein. To clearly explain the disclosure in the drawings, parts unrelated to the explanation are omitted, and similar parts are given similar drawing reference numerals throughout the specification.

Terms such as first and second and terms such as A and B may be used to describe various components, but the components should not be limited by the terms. The terms are used solely to distinguish a component from another. In some embodiments, without departing from the scope of the disclosure, a first component could be referred to as a second component, and similarly, the second component could also be referred to as the first component. The term and/or may include any combination of a plurality of related described items or any one of a plurality of related described items.

Throughout the specification, when a part is said to be “connected (linked, contacted, coupled)” to another part, this may include not only cases where they are “directly connected” to each other, but also cases where they are “indirectly connected” to each other with another member interposed therebetween. In some embodiments, when a part is said to “include” a component, this does not mean that the part excludes other components, but rather that the part may further include other components, unless otherwise specifically stated.

The terms used herein are for the purpose of describing particular embodiments and is not intended to limit the disclosure. Singular expressions may include plural expressions unless the context clearly indicates otherwise.

In the specification, terms such as “include” or “have” are intended to specify the presence of a feature, number, step, operation, component, part or combination thereof described in the specification, but should be understood not to exclude in advance the possibility of the presence or addition of one or more other features, numbers, steps, operations, components, parts or combinations thereof.

When an element or a layer is referred to as being “on” or “above” another element or layer, this includes not only a case where the element or layer is positioned directly on the top of the other element or layer, but also a case where another layer or element is interposed therebetween. Meanwhile, when an element or a layer is referred to as being “directly on” or “immediately on” another element or layer, it indicates a case where no other element or layer is interposed therebetween.

An initial wafer having a thickness of approximately 775 μm may be used. In a wafer processing process, such a wafer is processed to have a preset thickness of 100 μm or less, but a final thickness of the wafer may vary depending on a type of semiconductor product or customer requirements. Such a wafer processing process may be performed in the following order: rough machining, in which a wafer is polished from an initial thickness to a preset first thickness, grinding, in which the wafer is polished from the thickness in the rough machining to a second thickness thinner than the first thickness, and polishing, in which a back surface of the wafer polished in the grinding is polished to a final thickness by using polishing liquid.

The wafer may include silicon (Si), or a semiconductor material other than silicon, such as gallium nitride (GaN) or silicon carbide (SiC). However, a wafer of the disclosure is not limited in material, shape, structure, size, or the like. To reduce damage to a surface of the wafer, a protection tape including resin having the same diameter as the wafer may be attached to the surface of the wafer. The surface of the wafer may have a pattern implemented and may be cut to a size of an analysis sample.

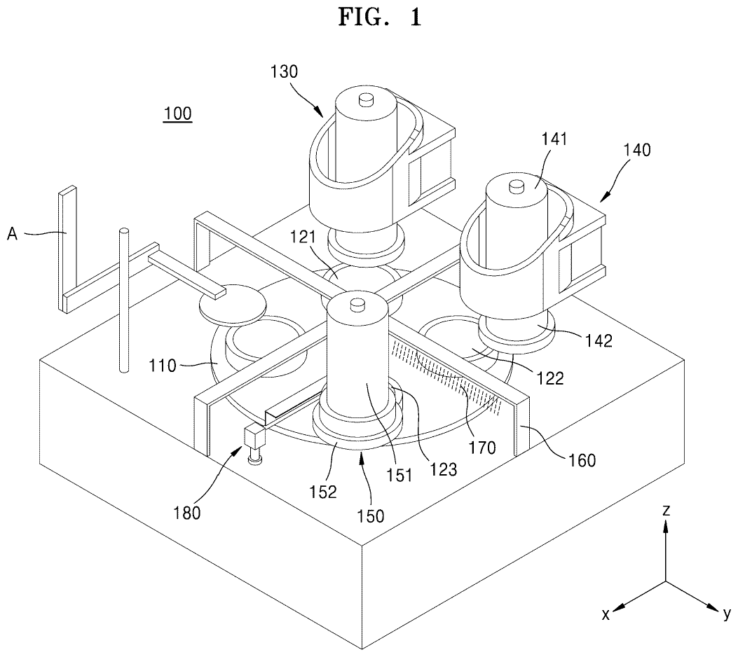

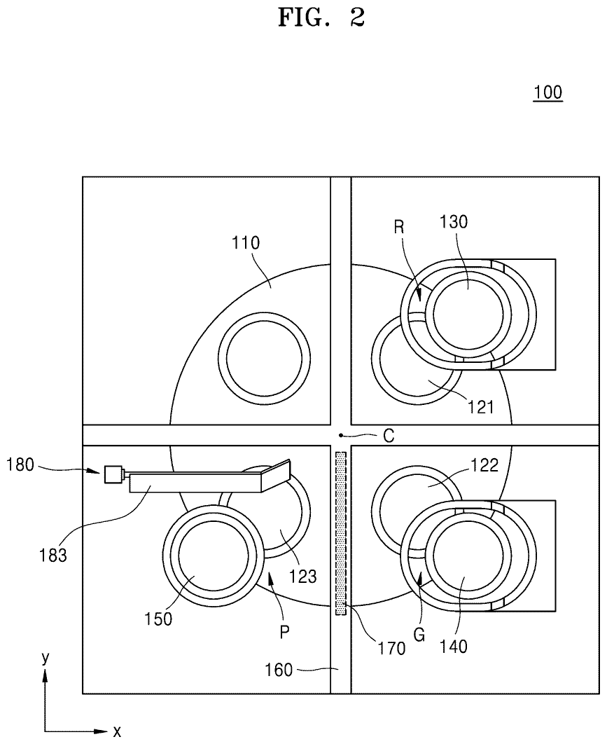

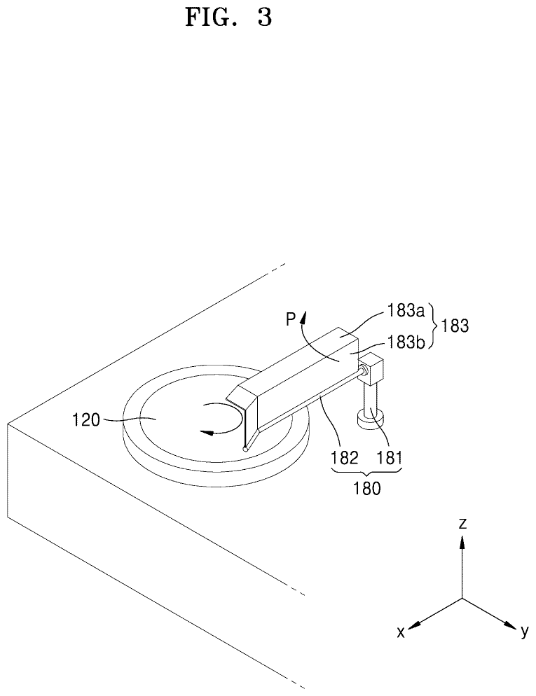

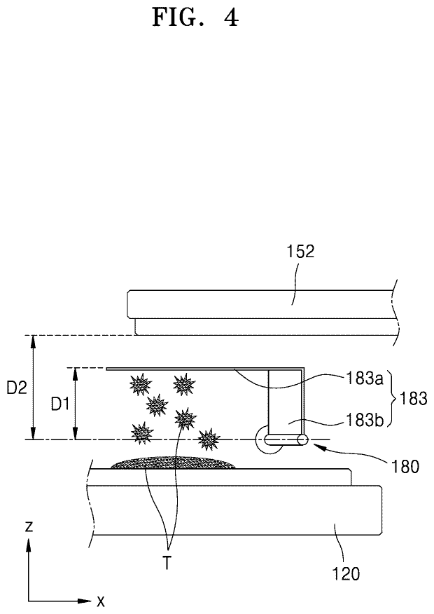

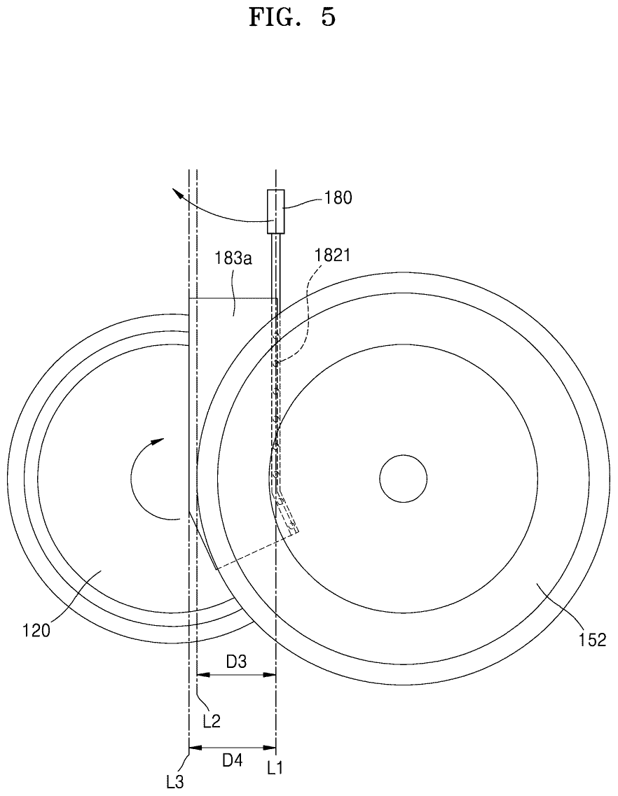

FIG. 1 is a perspective view of a wafer processing apparatus according to an embodiment of the disclosure, and FIG. 2 is a plan view of the wafer processing apparatus of FIG. 1. FIG. 3 is a drawing showing a part of a polishing area of the wafer processing apparatus of FIG. 1, FIG. 4 is a side view of the polishing area of the wafer processing apparatus of FIG. 1, and FIG. 5 is a plan view of FIG. 4 viewed from above.

Hereinafter, the structure and operation of a wafer processing apparatus 100 according to an embodiment of the disclosure will be specifically described with reference to FIGS. 1 to 5.

A wafer processing apparatus 100 according to an embodiment of the disclosure may include a turn table 110, chuck tables 120, a rough machining member 130, a grinding member 140, a polishing member 150, a frame 160, a moisture removal unit 170, and a swing nozzle 180.

The turn table 110 may rotate around a center axis C to align a wafer in a grinding area G and a wafer in a polishing area P.

The turn table 110 may be manufactured in a disk shape and may be rotated at a certain angle at preset intervals so that wafers mounted on the turn table 110 may be rough machined, ground, or polished. In some embodiments, as shown in the drawing, in case that the wafer processing apparatus 100 performs three processes: a rough machining process, a grinding process, and a polishing process, the wafer processing apparatus 100 may be divided into four areas including a wafer preparation area, and in this case, the turn table 110 may rotate at an angle of 90 degrees. However, the disclosure is not limited thereto, and in case that the apparatus only includes the grinding process and the polishing process, it is of course possible to rotate at an angle of 120 degrees. A bearing may be coupled to the center axis C of the turn table 110 to enable smooth rotation.

The turn table 110 may collectively rotate and move the chuck tables 120 so that any chuck table 120 may be positioned at a position of an adjacent chuck table 120 by rotation when each process of the wafer processing process is in progress.

At a bottom of the turn table 110, a rotation driving unit (not shown) for rotating the turn table 110 may be arranged so that the turn table 110 may be rotated according to a preset time.

The chuck tables 120 may be arranged on the turn table 110 and each may provide a space for a wafer to be mounted.

The chuck tables 120 may be installed radially at edge portions of the turn table 110 along a circumferential direction of the turn table and may rotate at a preset angle together with the turn table 110 according to the rotation of the turn table 110.

In the specification, among the chuck tables 120, a chuck table 120 positioned in an area where a wafer waits may be named as a waiting table, a chuck table 120 positioned in a rough machining area R may be named as a first chuck table 121, a chuck table 120 positioned in the grinding area G may be named as a second chuck table 122, and a chuck table 120 positioned in the polishing area P may be named as a third chuck table 123.

In the waiting area, a wafer may be supplied or a processed wafer may be removed. At this time, a transfer member A may transfer wafers one by one from a cassette (not shown) to the waiting table. The transfer member A may be a robot arm and may transfer the wafers by suction. The first chuck table 121, the second chuck table 122, and the third chuck table 123 may have a rough machining member 130, a grinding member 140, and a polishing member 150 arranged on upper portions of the chuck tables, respectively, and each may provide a space for processing a wafer adsorbed on the corresponding chuck table 120.

The rough machining member 130 may process a wafer arranged in the rough machining area by rough machining.

In some embodiments, the rough machining member 130 is used to roughly grind (rough machine) a back surface of the wafer to reduce a thickness of the wafer, and the back surface of the initial wafer may be roughly ground through a rough machining wheel. The rough machining wheel has an abrasive particle size of 700 to 900 mesh, for example, 800 mesh, and may roughly polish a surface of a wafer to leave a remaining thickness of the wafer that is 20 to 60 μm greater than a target final thickness.

The grinding member 140 may grind a wafer positioned in the grinding area G.

In some embodiments, the grinding member 140 may finely grind a wafer arranged in the grinding area G, the wafer being transferred thereto by rotation of the turn table 110 after rough machining.

The grinding member 140 is for processing a surface of the wafer roughly polished by the rough machining member 130 to a predetermined primary target thickness and may include a grinding wheel 142 and a first rotating member 141 for rotating the grinding wheel 142.

The first rotating member 141 may be coupled to the grinding wheel 142 to provide power for rotating the grinding wheel 142. The first rotating member 141 may be controlled in terms of rotation speed, rotation direction, or the like by a control unit (not shown).

The first rotating member 141 may be a spindle motor. At this time, the first rotating member may include a structure in which the grinding wheel 142 is coupled to a center axis of the spindle motor.

The grinding wheel 142 may be detachably mounted at a bottom of the first rotating member 141 and rotate by receiving power from the first rotating member 141 to grind a wafer. The grinding wheel 142 may perform polishing of the wafer through rotational friction by contacting the wafer while rotating at high speed.

The grinding wheel 142 has an abrasive particle size of 10,000 to 15,000 mesh, for example, 12,000 mesh, and may finely polish a back surface of the rough machined wafer to a target thickness.

The polishing member 150 may polish the wafer ground by the grinding member 140.

In some embodiments, the polishing member 150 may chemically and physically polish the wafer arranged in the polishing area P by rotation of the turn table 110 after the grinding process is completed.

The polishing member 150 may include a polishing wheel 152 and a second rotating member 151 for rotating the polishing wheel 152.

The second rotating member 151 may be coupled to the polishing wheel 152 to provide power for rotating the polishing wheel 152. In some embodiments, the second rotating member 151 may be a spindle motor.

The polishing wheel 152 may perform polishing by repeating linear movement and rotational movement along a curved surface while in contact with a wafer.

A hardness of the polishing wheel 152 is higher than that of the wafer, so that a workpiece surface of the wafer may be polished.

The polishing wheel 152 may include a polishing pad including foamed urethane or non-woven material. However, it is not limited thereto, and any material for polishing a wafer may be adopted without limitation.

The first rotating member 141 and the second rotating member 151 may be operated by being connected to the control unit (not shown). The control unit (not shown) may receive data regarding a polishing range of a wafer and generate a control signal to rotate each of the grinding wheel 142 and the polishing wheel 152 according to a preset value corresponding to the data.

The frame 160 may separate the grinding area G and the polishing area P from each other on the turn table 110.

The moisture removal unit 170 may be arranged on the frame 160 which separates the grinding area G and the polishing area P from each other.

The moisture removal unit 170 may be arranged on the frame 160 and may remove moisture from a wafer moving from the grinding area G to the polishing area P by rotation of the turn table 110.

The moisture removal unit 170 according to an embodiment of the disclosure may include an air nozzle which sprays gas at a preset angle toward a wafer. The air nozzle may remove moisture T by blowing air toward a chuck table 120 in the form of an air curtain or air knife.

An angle at which the air nozzle supplies air may be adjusted within a range from 0 to 90 degrees, when a direction perpendicular to the turn table 110 is 0 degrees, and a direction parallel to the turn table 110 and facing the second chuck table 122 is 90 degrees.

The air nozzle may be fixed at a preset angle to spray air and may also spray air while continuously rotating between 0 and 90 degrees as needed.

In case that the air nozzle rotates and sprays air, the air is evenly sprayed onto the second chuck table 122 to efficiently remove moisture T.

At this time, rotation speed of the air nozzle may be controlled by the control unit (not shown) and may vary depending on an amount of residual moisture T on the chuck table 120. The air nozzle may be operated by detecting the amount and distribution of residual moisture T by the control unit (not shown). In some embodiments, in case that moisture T is concentrated on a part of a wafer, the air nozzle may be fixed at a certain angle to supply air to a part requiring concentrated drying, and in case that the moisture is evenly distributed on the wafer, the air nozzle may rotate to dry an entire surface of the wafer.

The moisture removal unit 170 may primarily dry residual moisture T remaining on a top of the second chuck table 122 of the grinding area G after the grinding process. Therefore, wafer drying time performed in the polishing area P may be shortened and drying efficiency may be increased.

As another embodiment of the disclosure, a moisture removal unit 170 may remove moisture T on a top of a chuck table 120 by absorbing or wiping moisture, such as with a sponge or brush.

In some embodiments, as another embodiment of the disclosure, a sponge and brush may be arranged together with the air nozzle. As a wafer dries due to air discharged from the air nozzle, the moisture T may be absorbed through the sponge or the moisture T may be wiped away through the brush, thereby removing moisture. In this case, the moisture T on the wafer may be removed more efficiently.

In some embodiments, a wafer surface from which moisture has been primarily removed through the moisture removal unit 170 may be dried secondarily through the swing nozzle 180 in the polishing area P.

The swing nozzle 180 may be arranged between each of the chuck tables 120 and the polishing wheel 152 to spray gas toward the wafer. The swing nozzle 180 may remove the moisture T remaining on the wafer by spraying air onto the wafer.

At this time, the swing nozzle 180 may control pressure of the air being sprayed. The wafer processing apparatus 100 of the disclosure may increase accuracy of polishing by appropriately controlling the air pressure sprayed from the swing nozzle 180, and may easily remove waste water or particles generated during the polishing process.

The swing nozzle 180 may include a driving unit 181 and a nozzle portion 182.

The driving unit 181 may be arranged at a certain height in a direction intersecting with a rotation direction of the swing nozzle 180. At this time, the driving unit 181 may rotate the swing nozzle 180 from an edge portion of a wafer toward a center of the wafer toward the center axis C.

The driving unit 181 may include a motor (not shown) which rotates the swing nozzle 180. In some embodiments, a control unit (not shown) may be further included to spray air until an entire wafer surface is dry and to stop spraying in case that the entire surface is dry.

The nozzle portion 182 may spray air onto a wafer arranged on a chuck table 120 while rotating around the driving unit 181 at the top of the chuck table 120.

An end of the nozzle portion 182 may be arranged on the top of the chuck table 120, and the end may be formed in a curved shape so that air may be easily sprayed to the entire circular wafer.

Air may be sprayed through one or more air holes 1821 arranged in the nozzle portion 182.

The air hole 1821 may be formed in a long slit shape or may be formed as a plurality of holes.

The more air holes 1821 there are, the faster drying may be possible, and in case that a plurality of the air holes 1821 are arranged at regular intervals, a wafer may be dried evenly.

A swing nozzle cover 183 may be arranged on the top of the swing nozzle 180.

The swing nozzle cover 183 may extend from the swing nozzle 180 to cover a space between a chuck table 120 and the polishing wheel 152. The swing nozzle cover 183 may have a shape in which an end thereof is bent to correspond to the shape of the nozzle portion 182. The swing nozzle cover 183 may cover the moisture T from being sprayed to other components of the wafer processing apparatus 100, including the polishing wheel 152, due to the air sprayed from the swing nozzle 180. As a comparative embodiment, in case that the swing nozzle 180 does not include a swing nozzle cover, the faster a swing speed of the swing nozzle 180, the wider a range in which the moisture T may be scattered, so there is a limit to the swing speed of the swing nozzle 180.

In contrast, the wafer processing apparatus 100 according to an embodiment of the disclosure may include the swing nozzle cover 183, so that even if the swing nozzle 180 rotates rapidly, contamination of other components due to the scattering of the moisture T may be prevented, and thus the swing speed of the swing nozzle 180 may be increased without any restriction on the swing speed of the swing nozzle 180.

Through this, the wafer processing apparatus 100 of the disclosure may quickly remove moisture from a wafer during the dry polishing process, thereby shortening the dry polishing process time and improving overall productivity.

The swing nozzle cover 183 may prevent contamination of the polishing wheel 152 and reduce an occurrence of a processing defect during the dry polishing.

The swing nozzle cover 183 may include a column portion 183b and a wing portion 183a.

The column portion 183b may extend in a direction (z direction) intersecting with a direction in which the swing nozzle 180 moves. In some embodiments, the column portion 183b may extend toward the polishing wheel 152 and may have a certain height.

Referring to FIG. 4, a height D1 of the column portion 183b may be shorter than a distance D2 from the swing nozzle 180 to the polishing wheel 152. Therefore, the swing nozzle cover 183 may prevent the contamination of the polishing wheel 152 within a range which does not cause interference with the polishing wheel 152.

The wing portion 183a may extend from an end of the column portion 183b in a direction (x direction in FIG. 4) parallel to the direction in which the swing nozzle 180 moves.

The wing portion 183a may prevent the moisture T from scattering, thereby preventing the components inside the wafer processing apparatus 100, including the polishing wheel 152, from being contaminated.

Referring to FIG. 5, in case that the swing nozzle 180 is positioned between a chuck table 120 and the polishing wheel 152, a width D4 of the wing portion 183a may be greater than the longest distance D3 from the swing nozzle 180 to an edge of the polishing wheel 152 when viewed in a plan view (x-y plane).

Accordingly, the swing nozzle cover 183 may quickly remove moisture from a wafer by increasing the swing speed of the swing nozzle 180 during the wafer drying process through the swing nozzle 180. Accordingly, the swing nozzle cover 183 may not only improve the productivity of the wafer processing apparatus 100 by shortening the dry polishing process time, but also effectively prevent the polishing wheel 152 from being contaminated by the moisture T scattering onto the polishing wheel 152.

The wafer processing apparatus 100 according to an embodiment of the disclosure may include the moisture removal unit at an end of the frame, so that moisture on a top of a wafer may be primarily removed before the wafer moves from the grinding area G to the polishing area P.

Accordingly, the wafer processing apparatus 100 may improve polishing quality and shorten wafer drying time during the dry polishing process performed in the polishing area P. In some embodiments, the wafer processing apparatus 100 may improve the productivity of the wafer processing apparatus 100 by shortening the wafer drying time, which takes the longest time.

In some embodiments, the wafer processing apparatus 100 may shorten the dry polishing process time by arranging the swing nozzle cover 183 on the top of the swing nozzle 180, and may minimize scattering of the moisture T, waste water, particles, or the like to other components of the wafer processing apparatus 100, including the polishing wheel 152. Accordingly, the wafer processing apparatus 100 may perform the more accurate polishing process through the uncontaminated polishing wheel 152, and an overall lifespan of the wafer processing apparatus 100 may be increased.

The wafer processing apparatus according to an embodiment of the disclosure may primarily dry a wafer by installing the moisture removal unit between the grinding area and the polishing area, thereby shortening the dry polishing time. In some embodiments, the wafer processing apparatus may shorten the overall polishing process time, enabling economical and efficient polishing.

In some embodiments, the wafer processing apparatus may prevent particles or polishing water from scattering to other components of the wafer processing apparatus during dry polishing by arranging the swing nozzle cover on the top of the swing nozzle in the polishing area, and may shorten the dry polishing process time by enabling rapid rotation of the swing nozzle.

The effects of the disclosure are not limited to the effects described above, and should be understood to include all effects that may be inferred from the detailed description of the disclosure or the composition of the disclosure described in the claims.

The description of the disclosure is for illustrative purposes only, and a person having ordinary skill in the art to which the disclosure pertains will understand that the disclosure may be easily modified into other specific forms without changing the technical idea or essential characteristics of the disclosure. Therefore, it should be understood that the embodiments described above are exemplary in all respects and not limited thereto. In some embodiments, each component described as a single entity may be implemented in a distributed manner, and likewise, components described as distributed may be implemented in a combined manner.

The scope of the disclosure is indicated by claims described below, and all changes or modifications derived from the meaning and scope of the claims and their equivalent concepts should be interpreted as being included in the scope of the disclosure.

What is claimed is:

1. A wafer processing apparatus, comprising:
a turn table which rotates around a center axis and is positioned in alignment with a grinding area for grinding a wafer and a polishing area for polishing a wafer;
a plurality of chuck tables arranged on the turn table and configured to seat the wafers;
a grinding member for grinding the wafer positioned in the grinding area;
a polishing member for polishing the wafer ground by the grinding member;
a frame separating the grinding area and the polishing area from each other on the turn table; and
a moisture removal unit arranged on the frame and removing moisture from the wafer moving from the grinding area to the polishing area by rotation of the turn table.

2. The wafer processing apparatus of claim 1, wherein
the moisture removal unit includes an air nozzle which sprays gas at a preset angle toward the wafer.

3. The wafer processing apparatus of claim 1, wherein
the grinding member includes:
a grinding wheel; and
a first rotating member for rotating the grinding wheel.

4. The wafer processing apparatus of claim 1, wherein
the polishing member includes:
a polishing wheel; and
a second rotating member for rotating the polishing wheel.

5. The wafer processing apparatus of claim 1, comprising
a swing nozzle arranged between the chuck table and a polishing wheel in the polishing area and spraying gas toward the wafer.

6. The wafer processing apparatus of claim 5, comprising
a swing nozzle cover extending from the swing nozzle to cover in between the chuck table and the polishing wheel.

7. The wafer processing apparatus of claim 6, wherein
the swing nozzle cover includes a column portion extending from the swing nozzle in a direction intersecting with a direction in which the swing nozzle moves, and a wing portion extending from an end of the column portion in a direction parallel to a direction in which the swing nozzle moves.

8. The wafer processing apparatus of claim 7, wherein
in case that the swing nozzle is positioned between the chuck table and the polishing wheel, a width of the wing portion is greater than the longest distance from the swing nozzle to an edge of the polishing wheel when viewed in a plan view.

9. The wafer processing apparatus of claim 7, wherein
a height of the column portion is shorter than a distance from the swing nozzle to the polishing wheel.

10. A wafer processing apparatus, comprising:
a turn table which rotates around a center axis and is positioned in alignment with a grinding area for grinding a wafer and in a polishing area for polishing a wafer;
a plurality of chuck tables arranged on the turn table and configured to seat the wafers;
a grinding member for grinding the wafer positioned in the grinding area;
a polishing member for polishing the wafer ground by the grinding member; and
a frame separating the grinding area and the polishing area from each other on the turn table, wherein
the polishing area includes a swing nozzle arranged between the chuck tables and the polishing member in the polishing area and spraying gas toward the wafer and
a swing nozzle cover extending from the swing nozzle to cover in between the chuck table and a polishing wheel.

11. The wafer processing apparatus of claim 10, wherein
the nozzle cover includes a column portion extending from the swing nozzle toward the polishing wheel and a wing portion extending from the column portion toward a center of the chuck table.

12. The wafer processing apparatus of claim 11, wherein
in case that the swing nozzle is positioned between the chuck table and the polishing wheel, a width of the wing portion is greater than the longest distance from the swing nozzle to an edge of the polishing wheel when viewed in a plan view.

13. The wafer processing apparatus of claim 11, wherein
a height of the column portion is shorter than a distance from the swing nozzle to the polishing wheel.
